(19) United States
(12) Patent Application Publication
(10) Pub. No.: US 2023/0036201 A1
(43) Pub. Date: Feb. 2, 2023

(54) LEADLESS SEMICONDUCTOR PACKAGE WITH DE-METALLIZED POROUS STRUCTURES AND METHOD FOR MANUFACTURING THE SAME

(71) Applicant: STMICROELECTRONICS, INC., Calamba City (PH)

(72) Inventor: Ian Harvey Juralbal ARELLANO, Bauang (PH)

(73) Assignee: STMICROELECTRONICS, INC., Calamba City (PH)

(21) Appl. No.: 17/811,804

(22) Filed: Jul. 11, 2022

Related U.S. Application Data
(60) Provisional application No. 63/227,859, filed on Jul. 30, 2021.

(51) Int. Cl. H01L 23/495; H01L 23/31

(52) U.S. Cl. CPC H01L 23/49582; H01L 23/3107; H01L 23/49541; H01L 2224/73265; H01L 24/73

(57) ABSTRACT

A semiconductor package device having a porous copper adhesion promoter layer is provided. The porous copper adhesion promoter layer developed via de-metallization of the intermetallic compound layer grown after the thermal treatment of a thin metal layer plated on the copper base material. The highly selective de-metallization of the intermetallic compound layer ensures that the plated surfaces are not affected and does not create wire-bondability issues. The porous copper layer solves the delamination between the carrier and the epoxy molding compound by providing mechanical interlock features. Further, increasing the surface area of contact between the carrier and the epoxy molding compound improves the mechanical interlock features.

### BACKGROUND

### Technical Field

The present disclosure relates to designs for irregular surfaces in packaged semiconductor devices.

### Description of the Related Art

Delamination is one of the technical problems in the semiconductor packaging space. Delamination is a result of a weak interfacial interaction between two or more materials, which causes reliability failures for semiconductor packages.

One of the approaches in the related art to resolve delamination in semiconductor packaging is using adhesion promoters. Adhesion promoters are physical or chemical configurations introduced on a surface to promote adhesion between two or more materials, for example, between a lead frame and an epoxy molding compound (also referred to as EMC) or between a lead frame and a die attach material, or the like. These configurations work by providing physical or chemical interlocking mechanisms that enhance the integrity of the interface.

Adhesion promoters in the related art are used to prevent delamination but one or more approaches in the related art still caused reliability concerns both in front end and the back end of semiconductor products.

### BRIEF SUMMARY

The present disclosure is directed to a solution for delamination problems in chip packages. For example, one or more embodiments of the present disclosure provide a method for selectively roughening the exposed metal surface (e.g., body of the leads and the pads) thereby introducing mechanical interlock sites, and increasing the surface area for increased interfacial interaction with a molding substance such as an epoxy molding compound.

Further, one or more embodiments prohibit moisture ingression in semiconductor packages occurring through delaminated interfaces. Accordingly, the embodiments of the present disclosure improve the interfacial integrity between various materials. In addition, the reliability of the semiconductor packages is improved.

One embodiment of the present disclosure includes a method of forming an irregular surface on a first metal layer by applying a thermal treatment to the first metal layer and a second metal layer that is on the first metal layer. The method includes removing the second metal layer and exposing the irregular surface of the first metal layer. The method includes forming a molding substance on the first metal layer and within pores of the irregular surface.

Another embodiment of the present disclosure includes a semiconductor structure that includes a leadframe having a first metal structure. The first metal structure has a first surface and a second surface transverse to and extending from the first surface. The first surface has a first surface texture with a plurality of extensions and recesses. The semiconductor structure includes a molding substance or compound interlocking with the plurality of extensions and recesses at the first surface of the first metal structure.

Another embodiment is directed to a semiconductor package that includes a leadframe having a die pad and a plurality of leads. Interior surfaces of the die pad and the plurality of leads includes a tiered or stepped sidewalls or surfaces. The stepped sidewalls of the die pad face ones of the stepped walls of the adjacent leads. The semiconductor package includes a semiconductor die on the die pad. The semiconductor package includes a first conductive layer on a surface of at least one of the plurality of leads that is transverse to the stepped surface. The semiconductor package further includes an intermetallic compound at the stepped surfaces. The intermetallic compound has an irregular surface into which molding compound is formed to securely couple the molding compound to the leadframe.

### BRIEF DESCRIPTION OF THE SEVERAL VIEWS OF THE DRAWINGS

Reference will now be made by way of example to the accompanying drawings. In the drawings, identical reference numbers identify similar elements or acts. In some drawings, however, different reference numbers may be used to indicate the same or similar elements. The shapes of various elements and angles are not necessarily drawn to scale, and some of these elements may be enlarged and positioned to improve drawing legibility:

FIG. 1 is a cross-sectional view of a packaged semiconductor device according to some embodiments of the present disclosure.

FIG. 2 is an enlarged view of region ‘A’ generally showing a surface of a substrate.

FIGS. 3A-3B are steps of a method of applying a thermal treatment to a thin second metal layer on a first metal layer.

FIGS. 4A-4B are cross-sectional views of a semiconductor package structure that includes the irregular surfaces according to some embodiments of the present disclosure.

FIGS. 5A-5E are example shapes of the irregular surfaces of an intermetallic compound according to some embodiments of the present disclosure.

FIG. 6 is a flow chart that illustrates a method of forming an irregular surface in a packaged semiconductor device in accordance with some embodiments.

### DETAILED DESCRIPTION

Technical advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments are provided so that this disclosure may be sufficiently thorough and complete to assist those skilled in the art to fully understand the scope of the present disclosure.

A shape, a size, a ratio, an angle, and a number disclosed in the drawings for describing embodiments of the present disclosure are merely an example. Thus, the present disclosure is not limited to the illustrated details. Like reference numerals refer to like elements throughout. In the following description, when the detailed description of the relevant known function or configuration is determined to unnecessarily obscure an important point of the present disclosure, the detailed description of such known function or configuration may be omitted.

In describing a position relationship, when a position relation between two parts is described as, for example, “on,” “over,” “under,” “adjacent,” or “next,” one or more other parts may be disposed between the two parts unless a more limiting term, such as “just” or “direct(ly),” is used.

It will be understood that, although the terms “first,” “second,” etc., may be used herein to describe various elements, these elements should not be limited by these terms. These terms are only used to distinguish one element from another. For example, a first element could be termed a second element, and, similarly, a second element could be termed a first element, without departing from the scope of the present disclosure. Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments as mentioned above.

As used in this specification and the appended claims, the singular forms “a,” “an,” and “the” include plural referents unless the content clearly dictates otherwise. It should also be noted that the term “or” is generally employed in its broadest sense, that is, as meaning “and/or” unless the content clearly dictates otherwise.

The embodiments of the present disclosure may be applied to various technical fields including semiconductor packaging. For example, leadless packages, and other similar packages with exposed metal (e.g., copper) surface interfaced with another material (e.g., including but not limited to organic materials) requiring reduced or zero delamination.

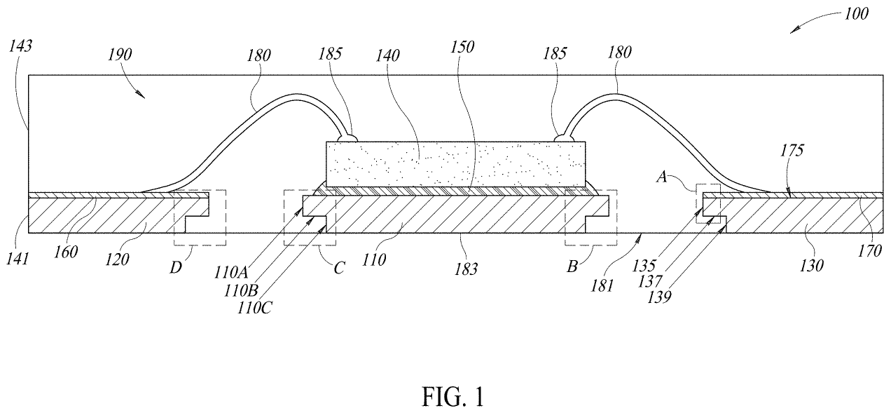

FIG. 1 is a cross-sectional view of a packaged semiconductor device according to some embodiments of the present disclosure.

As previously described, delamination between two surfaces due to weak interfacial interaction is a common failure mode in the related art. A typical week interaction between two surfaces in the semiconductor packaging space is the interface between a metal and a polymer. Within a packaged semiconductor device, an interaction between a leadframe surface and an epoxy molding compound is an example of an interface between a metal and a polymer. The strength of the interface between the metal and the polymer largely depends on the type and properties of the metal and the organic components included in the polymer. Metallic layers which are often used as a carrier base material has low affinity to organic polymers which causes the delamination within the packaged semiconductor device.

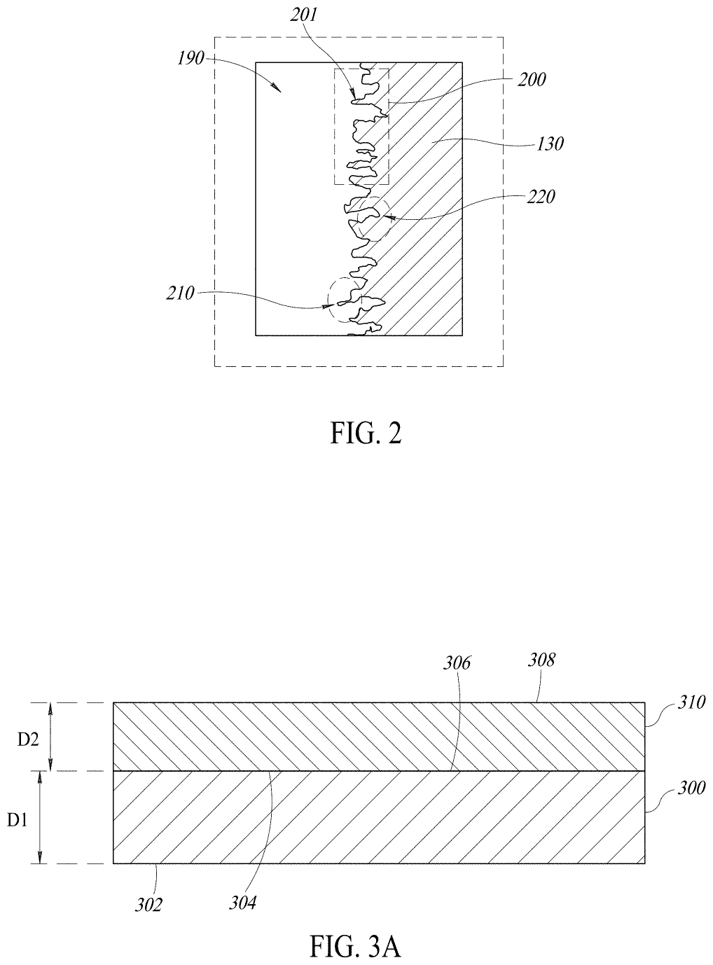

The packaged semiconductor device 100 shown in FIG. 1 is one example embodiment that addresses delamination. As will be further detailed in FIG. 2, the regions ‘A’, ‘B’, ‘C’, and ‘D’ are regions where the packaged semiconductor device 100 includes mechanical or electrochemical interlocking sites. These interlocking sites which include irregular, uneven surfaces, provides an enhanced interlocking mechanism between a metal and a polymer and improves the integrity of the interface. In some embodiments, the irregular surfaces includes a porous surface that has extensions and recessions (or peaks and valleys). The polymer which includes for example, an epoxy molding compound is in and fills the plurality of pores in the porous surface and interlocks with the metal layer. Accordingly, moisture ingression can also be prevented because the delaminated interfaces between the epoxy molding compound and the metal layer are minimized.

The packaged semiconductor device 100 includes a leadframe or a conductive substrate that includes a first part of the substrate 110, a second part of the substrate 120, and a third part of the substrate 130. The second part of the substrate 120 and the third part of the substrate 130 are arranged adjacent to the first part of the substrate 110, i.e. leads are on around a die pad. The packaged semiconductor device 100 further includes a semiconductor die 140, which is on the first part of the substrate 110. For example, the semiconductor die 140 includes a silicon die, integrated circuit die, or the like. A die attach material 150 may be provided between the semiconductor die 140 and the first part of the substrate 110 to couple the semiconductor die 140 to the first part of the substrate 110. The die attach material 150 may include a conductive or a non-conductive adhesive. Examples of die attach materials include silver epoxy paste or solder paste or the like. One integrated circuit die is shown in the drawings; however, alternatively, a packaged semiconductor device 100 may include two integrated circuit dies, or three or more integrated circuit dies, not shown, in accordance with some embodiments.

The semiconductor die 140 may include a semiconductor substrate including silicon or other semiconductor materials that includes a plurality of insulating and conductive layers to form active and passive components, elements, or circuits, not shown. The semiconductor elements may include transistors, diodes, capacitors, resistors, inductors, or the like. For example, the semiconductor die 140 may include a logic chip, a memory chip, a processor, an application specific device, or a chip having other functions.

The packaged semiconductor device 100 further includes a first conductive layer 160 on the second part of the substrate 120 and a second conductive layer 170 on the third part of the substrate 130. One non-limiting example of the first conductive layer 160 includes nickel-gold (e.g., gold layer stacked on top of nickel layer), nickel-palladium-gold, or the like. The second conductive layer 170 may have the same or similar material as the first conductive layer 160 and may be formed simultaneously or in the same processing steps.

The packaged semiconductor device 100 also includes a plurality of electrical connections, which are illustrated as wires 180. The wires 180 electrically connect the semiconductor die 140 to the first conductive layer 160 on the second part of the substrate 120 and the second conductive layer 170 on the third part of the substrate 130.

The packaged semiconductor device 100 includes a molding substance 190 that surrounds the die 140 and some surfaces of the leadframe. In some embodiments, the molding substance 190 may refer to an underfill material or a molding compound. The molding substance 190 is disposed between the various structures (e.g., the parts of the substrate 110, 120, 130, the semiconductor die 140, the die attach material 150, the conductive layer 160, 170, and the wire bonds 180) of the packaged semiconductor device 100.

The second part of the substrate 120 includes a first exterior edge or surface 141 that is uncovered or exposed from the molding substance 190. The molding substance 190 has a first exterior edge 143 that is coplanar with the first exterior edge 141 of the leadframe. In some embodiments, the conductive layer 160 also has an exterior edge that is coplanar with the first exterior edge 141 of the leadframe and the first exterior edge 143 of the molding compound. The third part of the substrate 130 also has an exterior edge that is coplanar with the respective edge of the molding compound on that side of the package.

The molding compound 190 is disposed around the semiconductor die 140 over the leadframe, which may be supported by a carrier during the manufacturing process. The molding compound 190 is formed using a laminating process or other process, in some embodiments. The molding compound 190 fills spaces around the semiconductor die 140 and around the first, second, and third parts of the substrate. The molding compound encapsulates the die 140. In some embodiments, the molding compound 190 includes a molding material and may include epoxy, an organic polymer, or a polymer with a silica-based or glass filler added. In some embodiments, the molding compound 190 includes a liquid molding compound (LMC) that is a gel type liquid when applied. Alternatively, the molding compound 190 may include other insulating materials and may be applied using other methods. The molding compound 190 is then cured using a heating process, infrared (IR) energy exposure process, an ultraviolet (UV) light exposure process, or other methods. In some embodiments the first part of the substrate 110 may be a die pad that is a conductive or metallic material, the second part of the substrate 120 may include a lead that is a conductive or metallic material. In some embodiments, the first part of the substrate 110 for the semiconductor die is generally formed from a metal or metal alloy, such as a copper substrate. The second part of the substrate 120 and the third part of the substrate 130 are the same material and are part of a single leadframe. They may be separated from the die pad with an etching process before the die has been attached.

One end of a wire bond 180 may be coupled to contact pads 185 on a top surface of the semiconductor die 140 and the other end of the wire bond 180 may be coupled to the first conductive layer 160 of the second part of the substrate 120. Similarly, one end of another wire bond 180 may be coupled to contact pads 185 on a top surface of the semiconductor die 140 and the other end of the wire bond 180 may be coupled to the second conductive layer 170 of the third part of the substrate 130.

The semiconductor die 140 will include additional contact pads or bond pads on the top surface. The contact pads 185 may include Al, Cu, other metals, or alloys thereof. The outer surfaces of the semiconductor die 140 includes an insulating material (not shown) including a passivation layer such as silicon nitride, silicon oxide, polybenzoxazole (PBO), or other insulators. Openings are formed in the insulating material below the contact pads 185 so that electrical connection can be made to vias which may include Cu or other metals. The third part of the substrate 130 includes a stepped feature that faces the die pad. The stepped feature includes a first surface 135 that is transverse to a second surface 175 of the leadframe. The first surface 135 contacts the molding substance 190 and the second surface 175 contacts the second conductive layer 170. In some embodiments, the second surface 175 may be referred to as a top surface of the third part of the substrate 130 and the first surface 135 may be referred to as a side surface of the third part of the substrate 130.

However, considering that the structure can be flipped in actual practice, the term “top” surface and “side” surface is used only with reference to FIG. 1.

The first surface 135 is roughened or made more irregular to form pores or peaks and valleys. A surface roughness of the first surface 135 is different from a surface roughness than the second surface 175. The second surface would be smoother than the first surface. That is, the first surface 135 has a first surface texture and the second surface 175 has a second surface texture that is different than the first surface texture. The first surface texture may exhibit relatively greater roughness than the second surface texture. The first surface 135 may also include relatively more porous surfaces or porous textures than the second surface 175.

The stepped feature includes a third surface that is adjacent and transverse to the first surface 135 of the third part of the substrate 130. The third surface 137 is substantially parallel the second surface 175 in some embodiments. A fourth surface 139 is adjacent and transverse to the third surface 137. Each of the third and fourth surfaces receive the treatment that makes the first surface more porous.

A bottom surface 181of the molding compound 190 is coplanar with a bottom surface 183 of the leadframe. The molding compound 190 between the leads and the die pad will be T-shaped in cross-section with a wider section being closer to the bottom surface and a narrower section spaced from the bottom surface by the wider section.

FIG. 2 is an enlarged view of region ‘A’ generally showing the first surface 135 of the third part of the substrate 130. Similar irregular surfaces will be formed on the third surface 137 as well as the fourth surface 139. Further, regions ‘B’, ‘C’, and ‘D’ includes similar irregular surfaces as region ‘A.’ For example, a first surface 110A of the first part of the substrate 110, a second surface 110B of the first part of the substrate 110, and a third surface 110C of the first part of the substrate 110 include the same or similar irregular surfaces shown in region ‘A.’ Thus, an enlarged view of regions ‘B’, ‘C’, and ‘D’ will be omitted. In addition, for illustration purposes, the detailed shape of the irregular surfaces on the first surface 135 will be described with reference to FIG. 2. In one or more embodiments, the second surface 175 includes a surface that is relatively more planar than the first surface 135.

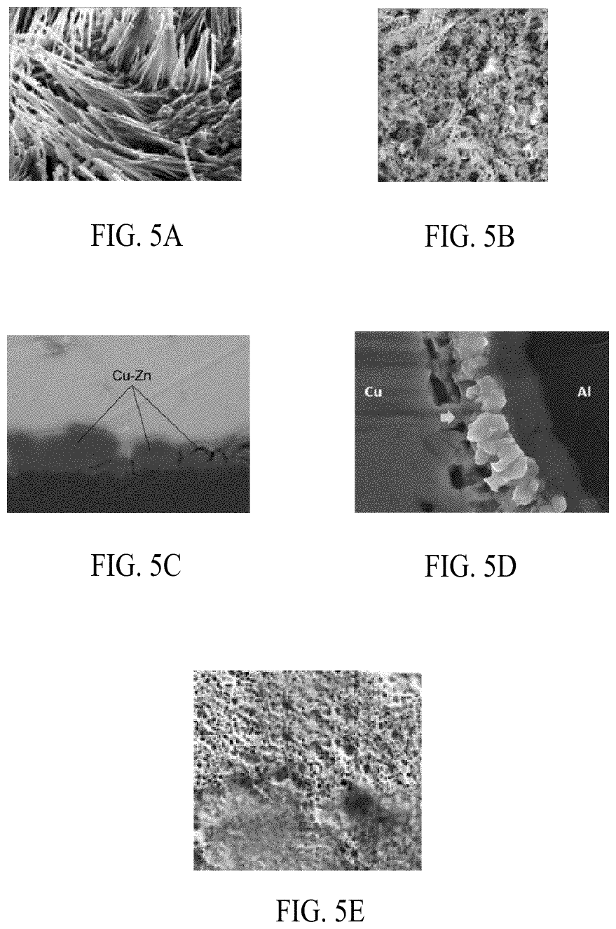

FIG. 2 is a cross-sectional, enhanced view of region ‘A’ which shows an example of an irregular surface 201 formed on the lead, which is the third part of the substrate 130. The irregular surface 201 includes peaks 210 and valleys 220 where adjacent peaks and valleys may have different dimensions. For example, in a region 200 there are a plurality of peaks that each have different or irregular dimensions in a first direction (top to bottom in the orientation of FIG. 2). Each of the valleys also have different dimensions along the first direction, such that an adjacent peak and valley have a different dimension along the first direction. Each of the peaks and valleys also have varying dimensions along a second direction that is orthogonal or transverse to the first direction. The second direction being left to right in the orientation of FIG. 2. The third part of the substrate 130 is metal or may include a metal layer. Further examples of the shapes, porosity, textures, and surface roughness of an irregular surface 200 that can be formed are shown in FIGS. 5A-5E.

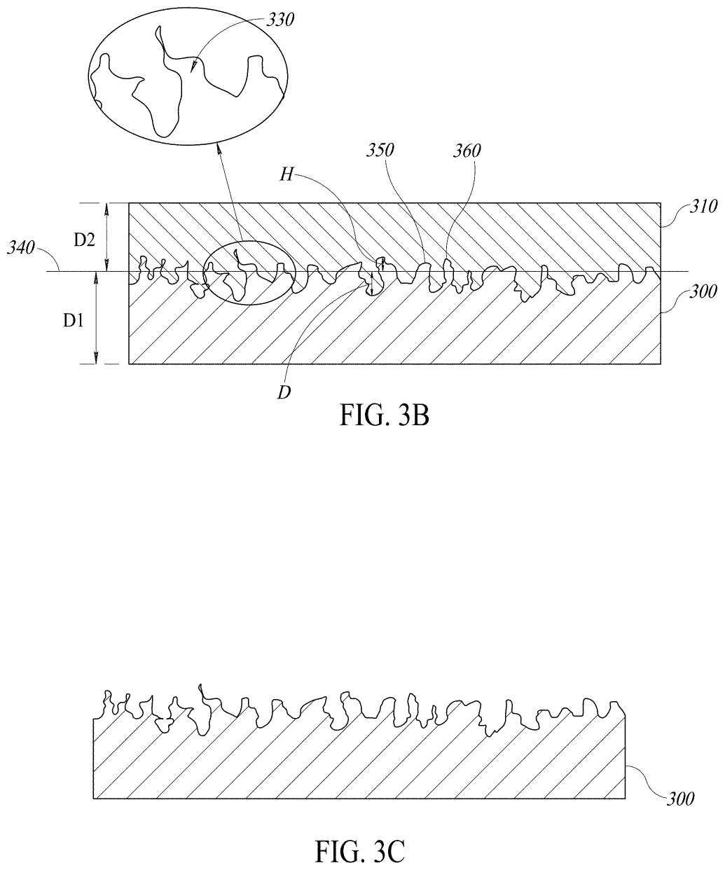

In some embodiments, the peaks may be referred to as extensions and the valleys may be referred to as recessions. There are multiple peaks 210 and multiple valleys 220 formed along the irregular surface 200 and the irregular surface 200 increases the contact sites and surface area, which increase the mechanical interlock sites between the molding substance 190 and the third part of the substrate 130. For instance, if the molding substance 190 and the third part of the substrate 130 had a planar contact surface between them, the surface contact area at the contact site between the molding substance 190 and the third part of the substrate 130 would have a significantly lesser surface contact area compared to that of the irregular surface 200 shown in FIG. 2. The relatively increased surface contact area between the molding substance 190 and the third part of the substrate 130 provides improved bonding between the two materials. Such interlocking configuration provides a solution to the delamination problem commonly found in the related art. Because the interlocking configuration created by the irregular, uneven surfaces, weak interfacial interaction between two surfaces, namely, between the molding substance 190 and the third part of the substrate 130, are avoided and the reliability of the semiconductor device is increased. The method of forming the irregular surfaces 200 will be further detailed in connection with FIGS. 3A-3C.

As described, the irregular surface 201 creates an improved mechanical interlocking site between the molding substance 190 and the third part of the substrate 130. The multiple peaks 210 and multiple valleys 220 form a jagged shape as shown in the cross-section. However, a three dimensional view of the same irregular surface 200 may include a surface having pores or a surface having a porous texture. In some instances, the valleys 220 as shown in FIG. 2 may correspond to the location of the pores. When the molding substance 190 is provided, the molding substance 190 permeates into the valleys 220 or the pores in the irregular surface and when it hardens, it physically interlocks with the third part of the substrate 130 at the irregular surface 200. This interlocking configuration reduces or minimizes the delamination occurring between the third part of the substrate 130 and the molding substance 190.

FIG. 3A is a method of forming an irregular surface at an interface of a first metal layer 300, such as part of a leadframe according to one or more embodiments of the present disclosure. A second metal layer 310 is formed on a first metal layer 300. The first metal layer 300 has a first dimension D1. The first dimension D1 is defined as a dimension between a first surface 302 of the first metal layer 300 and a second surface 304 of the first metal layer 300. For example, the first dimension D1 includes a length between the first surface 302 and the second surface 304 or a height or thickness of the first metal layer 300.

The second metal layer 310 which is formed on the first metal layer 300 has a second dimension D2. The second dimension D2 is defined as a dimension between a first surface 306 of the second metal layer 310 and a second surface 308 of the second metal layer 310. For example, the second dimension D2 includes a length between the first surface 306 and the second surface 308 or a height or thickness of the second metal layer 310. In some embodiments, the second dimension D2 is smaller than the first dimension D1. For example, the second dimension D2 may be about 1 to 5 microns (μm). However, in some embodiments, the second dimension D2 may be thicker than 5 microns or thinner than 1 micron. For example, if the second dimension D2 of the second metal layer 310 is provided to be thicker than 5 microns, the time for dissolving the second metal layer 310 may take more time and the amount of solvents to dissolve the second metal layer 310 may require more. Similarly, the second dimension D2 may be thinner than 1 micron. For example, the second dimension D2 may be 100 nm. However, if the second dimension D2 of the second metal layer 310 is 100 nm, the first metal layer 300 will be able to protrude towards the second metal layer 310 up to 100 nm at most. In this case, the level of surface roughness and porosity may not be enough to cure the delamination problems in the related art.

FIG. 3A illustrates that a relatively thinner metal layer, the second metal layer 310, being plated on the first metal layer 300 before thermal treatment is applied to the two metal layers 300, 310.

One example of the first metal layer 300 includes copper (Cu). One example of the second metal layer 310 includes aluminum (Al), tin (Sn), zinc (Zn), or the like. The examples provided above are non-limiting examples of metallic substances and other suitable metals can be used.

FIG. 3B is an example process of a thermal treatment applied to a first metal layer and a second metal layer according to one or more embodiments of the present disclosure. Applying a thermal treatment to a first metal layer 300 and a second metal layer 310 involves heating the first and the second metal layers 300, 310 to a selected temperature level. The type of thermal treatment and temperature level form an intermetallic compound based on an interaction of the first and the second metal layers 300, 310.

When thermal treatment is applied, the first metal layer 300 gradually deforms near the interface 340 which corresponds to the location where the first surface 304 of the first metal layer 300 (or the second surface 306 of the second metal layer 310) interact or are in contact. Portions of the first metal layer 300 begin to move and change shape, crossing the interface line 340 and protruding towards the second metal layer 310. Similarly, portions of the second metal layer 300 gradually deforms near the interface line 340 and the portions cross the interface 340 and protrudes towards the first metal layer 300. The protrusions of the first metal layer 300 into the second metal layer 310 and the protrusions of the second meal layer 310 into the first metal layer 300 creates the irregular surface 200 near the interface340. The thermal treatment of the first and second metal layers 300, 310 creates an intermetallic compound 330 or intermetallic compound layer near the interface340. The substance material that forms the jagged, irregular-shaped portions is the intermetallic compound 330 generated by applying thermal treatment to the first and second metal layers 300, 310.

A plurality of portions of the intermetallic compound 330 includes a plurality of peaks and a plurality of valleys similar to those shown in FIG. 2. The irregular surface 201 including the alternating peaks and valleys are formed continuously adjacent to the interface340. A height H of a peak may be defined by a length starting from the interface340 to the tip of the peak. A depth of a valley may be defined similarly. That is, a depth D of a valley may be defined by a length starting from the interface340 to the bottom of the valley. In some embodiments, the height H of the peak is based on the second dimension D2 of the second metal layer 310. For example, a peak cannot extend further beyond than the second dimension D2 of the second metal layer 310. Likewise, a depth D of a valley is smaller than the first dimension D1 of the first metal layer 300.

In some embodiments, a space between adjacent peaks defines a size of the pores of the irregular surface 200. The pores can also be defined by a space between a plurality of protruding portions of the intermetallic compound 330. For example, a space between a first protruding portion 350 of the intermetallic compound and a second protruding portion 360 of the intermetallic compound 330 defines the size of the pores. The size of the pores may vary based on the distance between the first protruding portion 350 and the second protruding portion 360.

One example of the first metal layer 300 includes copper (Cu). One example of the second metal layer 310 includes aluminum (Al), tin (Sn), zinc (Zn), or the like. Applying thermal treatment to the first and second metal layer 300, 310 allows the intermetallic compound to grow or form. If the first metal layer 300 includes copper and the second metal layer 310 includes aluminum, the intermetallic compound will have the form of CuₓAl_{y} (e.g., Cu₂Al, Cu₃Al, Cu₄Al₃, CuAl, CuAl₂, or the like). If the first metal layer 300 includes copper and the second metal layer 310 includes tin, the intermetallic compound will have the form of CuₓSn_{y} (e.g., Cu₃Sn₄, Cu₆Sn₅, or the like). If the first metal layer 300 includes copper and the second metal layer 310 includes zinc, the intermetallic compound will have the form of CuₓZn_{y} (e.g., CuZn, Cu₂Zn₃, CuZn₂, or the like).

FIG. 3C is an example metal dissolution or removal process applied to a second metal layer according to one or more embodiments of the present disclosure.

After the intermetallic compound is created, the second metal layer 310 used to create the intermetallic compound is removed using selective metal dissolution. In some embodiments, the selective metal dissolution process involves immersion of the second metal layer 310 in a solvent. This is a chemical process that substantially removes the second metal layer 310 from the first metal layer 300. In some cases, at least a portion of a residue (or traces) of the second metal layer 310 may exist adjacent to the pores, peaks, and valleys of the intermetallic compound 330. However, such presence of the residue of the second metal layer 310 does not impact the interfacial interaction of the intermetallic compound with the molding substance 190.

The first metal layer 300 that is distanced apart from the interface 340 may stay as its original material. For example, if the first metal layer 300 included copper, the region that is spaced apart from the interface340 will maintain its original metallic properties. Namely, the spaced apart region will remain as copper even after the thermal treatment. However, the first metal layer 300 that is near the interface 340 that abutted the second metal layer 310, transformed to a different type of metal, an intermetallic compound. Although FIG. 3C is shown as if the entire region as a first metal layer 300, this is not an accurate representation of the metallic properties and substance since the intermetallic compound has been formed after thermal treatment to the first and second metal layer 300, 310. The enlarged pop-up shown in FIG. 3B illustrates an accurate representation of the intermetallic compound.

If the first metal layer 300 includes copper and the second metal layer 310 includes aluminum, the selective metal solvent for removing aluminum includes H₃PO₄/HNO₃/CH₃COOH/H₂O, or the like. Similarly, if the first metal layer 300 includes copper and the second metal layer 310 includes tin, the selective metal solvent for removing tin includes CH₃SO₃H/surfactant/H₂O, or the like. If the first metal layer 300 includes copper and the second metal layer 310 includes zinc, the selective metal solvent for removing zinc includes H₂SO₄, or the like. The solvent provided herein is merely an example and a person of ordinary skill in the art will readily appreciate that other suitable metal solvents for dissolving aluminum, tin, or zinc can be used.

The use of selective metal solvent removes the second metal layer 310 and the removal using the solvent does not affect the bonding surfaces. For example, the copper in the first metal layer 300 and the aluminum in the second metal layer 310 forms an intermetallic compound in the form of CuₓAl_{y}. This intermetallic compound may introduce mechanical interlock regardless of design-specific size constraints. One or more embodiments of the present disclosure may increase the surface area of contact between the substrate (e.g., carrier) and the molding substance 190 (e.g., epoxy molding compound), thereby increasing the interfacial interaction between the two surfaces. The porous intermetallic compound layer developed through de-metallization of the second metal layer 310 acts as adhesion promoter which provides a more robust solution to delamination problems in the related art.

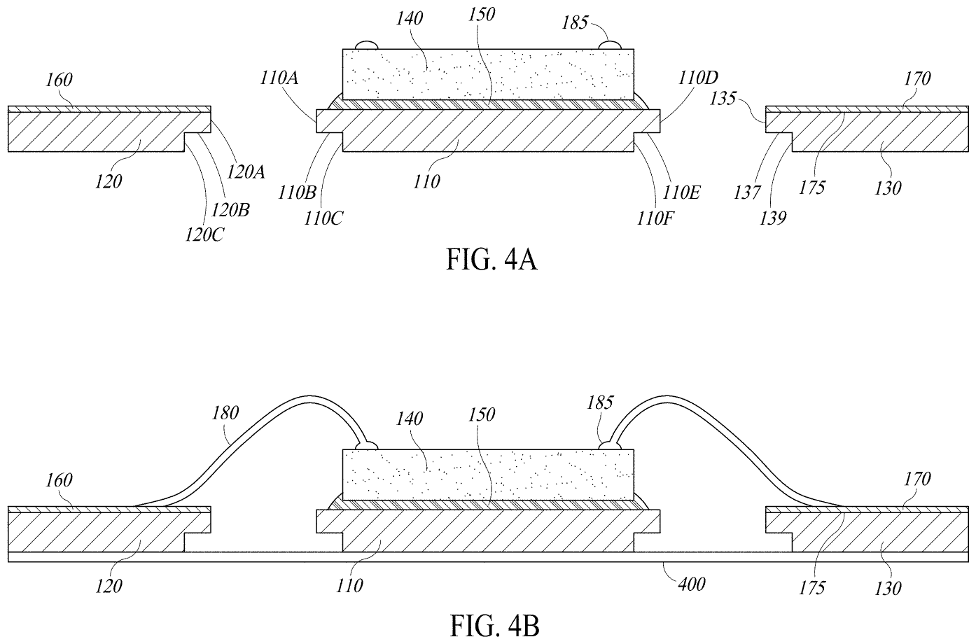

FIGS. 4A-4B are steps of an assembly process to form the package 100 that includes the irregular surfaces according to some embodiments of the present disclosure. The first part of the substrate 110, a second part of the substrate 120, and a third part of the substrate 130 are formed with either a stamping, etching or other suitable process to form the stepped or staggered edges of the leads and the die pad of the leadframe. The first conductive layer 160 is formed on the second part of the substrate 120 and the second conductive layer 170 is formed on the third part of the substrate 130. At this time, a semiconductor die 140 is not yet attached on to the first part of the substrate 110.

A thin metal layer may be provided on a first surface 120A, a second surface 120B, and a third surface 120C of the second part of the substrate 120. Other surfaces, not intended to receive an irregular surface will not be plated. A thin metal layer is also provided on a first surface 110A, a second surface 110B, a third surface 110C, a fourth surface 110D, a fifth surface 110E, and a sixth surface 110F of the first part of the substrate 110. In addition, a thin metal layer is provided on a first surface 135, a third surface 137, and a fourth surface 139 of the third part of the substrate 130.

After the plating of the thin metal layer is completed, a thermal treatment as described in connection with FIGS. 3A-3C is applied. The thermal treatment causes the intermetallic compound to grow and an irregular, porous surface is formed at the above listed surfaces of the first, second, and third part of the substrates 110, 120, 130.

A die attach material 150 is formed on the first part of the substrate 110 and a semiconductor die 140 is subsequently formed on the die attach material 150. The contact pads 185 are formed on the semiconductor die 140 for providing an electrical connection using wire bonds. In some embodiments, the die pad surface to which the die is attached is protected or prevented from having the irregular surface formed during the plating and thermal treatment process. However, in other embodiments, the die pad surface can also be bare and can have irregular surface after plating a metal and applying thermal treatment. In these embodiments, the formation of the irregular surface may promote interlocking with the die and the die attach material.

After the contact pads 185 are formed on the semiconductor die 140, wire bonds 180 are used to couple the second part of the substrate 120 to the semiconductor die 140 and the third part of the substrate 130 to the semiconductor die 140. In particular, one end of the wire bond 180 is coupled to the first conductive layer 160 and the opposite end of the wire bond 180 is coupled to the contact pad 185 on the semiconductor die 140. Similarly, one end of the wire bond 180 is coupled to the second conductive layer 170 and the opposite end of the wire bond 180 is coupled to the contact pad 185 on the semiconductor die 140.

Once wire bonding process is completed, a tape 400 is attached to the bottom of the first, second, and third part of the substrates 110, 120, 130 to secure the location of the substrates. After the taping process is completed, a molding substance 190 is provided on the entire structure. At this point, the molding substance 190 fills into the pores of the irregular surface (e.g., a first surface 120A, a second surface 120B, and a third surface 120C of the second part of the substrate 120; a first surface 110A, a second surface 110B, a third surface 110C, a fourth surface 110D, a fifth surface 110E, and a sixth surface 110F of the first part of the substrate 110; a first surface 135, a third surface 137, and a fourth surface 139 of the third part of the substrate 130) and hardens. The molding substance 190 interlocks with the irregular surface of the intermetallic compound and therefore provides a robust bond between the two materials. After the molding process is completed, the tape 400 is removed and the packaged semiconductor device is formed (see FIG. 1).

In some embodiments, an intermetallic compound layer is not formed on the first, second conductive layer 160, 170. The materials used such as nickel gold in the first, second conductive layer 160, 170 prevents the growth of an intermetallic compound layer.

This aspect is beneficial in that, if an intermetallic compound layer is formed on the first, second conductive layers 160, 170, this could create wire-bondability problems. Accordingly, the wire-bonding area (or wire-bonding surfaces) is preserved but the exposed surfaces of the first, second, and third part of the substrates 110, 120, 130 (e.g., exposed surfaces of copper if the substrates are a copper substrate) can form an intermetallic compound layer. This is beneficial from a standpoint of solving delamination problems as these are the surface areas (e.g., a first surface 120A, a second surface 120B, and a third surface 120C of the second part of the substrate 120; a first surface 110A, a second surface 110B, a third surface 110C, a fourth surface 110D, a fifth surface 110E, and a sixth surface 110F of the first part of the substrate 110; a first surface 135, a third surface 137, and a fourth surface 139 of the third part of the substrate 130) where delamination generally occurs. Accordingly, the process of forming a porous metal layer (e.g., intermetallic compound layer) that has an irregular surface can address both the wire-bondability problems and the delamination problems.

In some embodiments, the irregular surfaces on the first, second, and third part of the substrates may be formed any step or process before the wire bonding process. However, in other embodiments, the irregular surfaces on the first, second, and third part of the substrates may be formed any step or process before the molding substance 190 is provided.

FIGS. 5A-5E are example shapes of the irregular surfaces of an intermetallic compound according to some embodiments of the present disclosure.

FIGS. 5A-5E show various morphology of the intermetallic compound taken through an SEM (scanning electron microscope) image. As illustrated, the morphology of the intermetallic compound is distinct based on the particular metal used to form the intermetallic compound.

FIG. 5A is a top view of Cu—Sn intermetallic compound using a first magnification. For example, copper is used as a first metal layer 300 and tin is used as a second metal layer 310. The view shows Cu6Sn5 intermetallic compound having a fibrous-shaped or straw-shaped irregular surface. Due to the deep valleys or crevices, a solvent for de-metallizing tin (or the second metal layer 310) may not be able to reach all the way down to the deep valleys or crevices and some residues or traces of tin will be left within the irregular surfaces. However, these metal residues do not impact the interlocking site between the molding compound and the intermetallic compound.

FIG. 5B is a top view of Cu—Sn intermetallic compound using a second magnification different from a first magnification of FIG. 5A. The view shows the fibrous and porous surfaces of the intermetallic compound Cu₆Sn₅.

FIG. SC is a cross-sectional view of Cu—Zn intermetallic compound. The view shows the flakes and platelet-like shapes and surfaces of the intermetallic compound CuZn, Cu₅Zn₈.

FIG. 5D is a cross-sectional view of Cu—Al intermetallic compound. The view shows the columnar and tubular shapes and surfaces of the intermetallic compound Al₂Cu, AlCu, Al₄Cu₉.

FIG. 5E is a top view of Cu—Al intermetallic compound. The view shows the sponge-like, porous surfaces of the Cu—Al intermetallic compound.

As shown in FIGS. 5A-5E, the shape, surface textures, and the level of porosity of the intermetallic compound is distinct to the particular type of metal used. For example, a copper-tin intermetallic compound includes a fibrous shape, a copper-aluminum intermetallic compound includes a columnar, tubular shape, and a copper-zinc intermetallic compound includes a flake or platelet shape. These irregular surfaces acts as an adhesion promoter with the molding compound that may substantially reduce delamination. Based on the type of metal used to form the intermetallic compound, other shapes and textures of irregular surfaces may be formed.

The level of the temperature may affect the growth of the intermetallic compound. Further, the level of temperature used for heating the metals may depend on the type of metal used for forming the intermetallic compound. For example, the baking temperature of the metals may range from about 100 to 250° C.

Generally, applying higher temperature during thermal treatment may result in a faster growth of the intermetallic compound and the formation of the irregular surfaces. Comparing FIGS. 5A and 5B, even if the same material is used for forming the Cu—Sn intermetallic compound, the shape, size, surface, texture, level of porosity, or the like may differ based on the length of the thermal treatment applied. For example, in FIG. 5A, a longer thermal treatment has been applied which caused to create a long, straw-like fiber shape intermetallic compound. Because of the sufficient length of the thermal treatment, the intermetallic compound could grow and extend to a longer length. On the other hand, in FIG. 5B, a relatively shorter thermal treatment (e.g., about 1/10 of the time of FIG. 5A, heating applied at the same temperature) has been applied which also created a fibrous, porous surface in the intermetallic compound. However, as shown, the length of the protruding portions of the intermetallic compound is relatively shorter than those shown in FIG. 5A. To elaborate, when the first metal layer 300 and the second metal layer 310 are baked at a particular temperature depending on the type of the metal (e.g., 100-250 C) in an oven or other heating apparatus, the movement of the atoms of the first metal layer 300 will go up towards the second metal layer 310 as the energies of the atoms increase as temperature rises. Similarly, movement of the atoms of the second metal layer 310 will go down towards the first metal layer 300. The portions of the first and second metal layer become electrochemically intertwined to form an intermetallic compound. Further, as higher temperature is applied, the atoms of the metal will move faster. Likely, the longer the thermal treatment lasts, the intermetallic compound will have enough time to protrude outwards and grow. In some embodiments, a thickness of the intermetallic compound layer may range from about 100 nanometers to 5 micrometers.

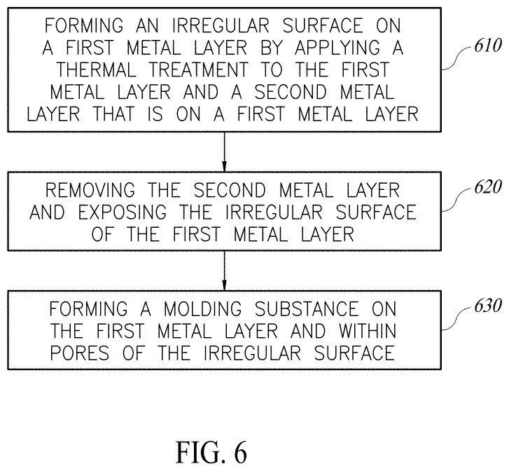

FIG. 6 is a flow chart that illustrates a method of forming an irregular surface in a packaged semiconductor device in accordance with some embodiments. The method shown in FIG. 6 is an example and other methods may also be used to create the irregular surfaces described herein. The flow chart will be described in conjunction with FIG. 1 and FIGS. 3A-3C.

In step 610 of the flow chart shown in FIG. 6, a second metal layer 310 is formed on a first metal layer 300. A thermal treatment is applied to both metal layers 300, 310 and an irregular surface is formed in the process of growing an intermetallic compound that is based on the first metal layer 300 and the second metal layer 310.

In some embodiments, applying thermal treatment to the first and second metal layers includes heating the first and the second metal layers and forming an intermetallic compound based on the first and the second metal layers.

In some embodiments, forming an intermetallic compound based on the first and the second metal layers includes forming a plurality of portions of the intermetallic compound protruding in a direction towards the second metal layer.

Forming an intermetallic compound based on the first and the second metal layers also includes forming a plurality of portions of the second metal layer protruding in a direction towards the first metal layer and between spaces of the plurality of portions of the intermetallic compound and forming an interlocking configuration based on the plurality of portions of the intermetallic compound. In one embodiment, the first metal layer has a first thickness and the second metal layer has a second thickness thinner than the first thickness of the first metal layer.

In step 620, a selective metal solvent is used to remove the second metal layer 310. The removal of the second metal layer 310 exposes the irregular surface of the first metal layer 300.

In some embodiments, dissolving the second metal layer and exposing the first metal layer includes selectively removing the second metal layer and ones of the plurality of intermetallic compounds.

Dissolving the second metal layer and exposing the first metal layer further include exposing the plurality of portions of the intermetallic compound and the first metal layer.

In some embodiments, the plurality of portions of the intermetallic compound includes a de-metallized porous layer.

In step 630, a molding substance 190 is formed on the first metal layer 300 and within the pores of the irregular surface.

In some embodiments, forming the molding substance on the first metal layer and within pores of the irregular surface includes interlocking one or more surfaces of the first metal layer and the molding substance. Here, the molding substance fills the pores on the one or more surfaces of the first metal layer and hardens.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
forming an irregular surface on a first metal layer by applying a thermal treatment to the first metal layer and a second metal layer that is on the first metal layer;
removing the second metal layer and exposing the irregular surface of the first metal layer; and
forming a molding substance on the first metal layer and within pores of the irregular surface.

2. The method of claim 1 wherein applying thermal treatment to the first and second metal layers includes:
heating the first and the second metal layers; and
forming an intermetallic compound based on the first and the second metal layers.

3. The method of claim 2 wherein forming an intermetallic compound based on the first and the second metal layers includes:
forming a plurality of portions of the intermetallic compound protruding in a direction towards the second metal layer;
forming a plurality of portions of the second metal layer protruding in a direction towards the first metal layer and between spaces of the plurality of portions of the intermetallic compound; and
forming an interlocking configuration based on the plurality of portions of the intermetallic compound.

4. The method of claim 3 wherein dissolving the second metal layer and exposing the first metal layer includes:
selectively removing the second metal layer and ones of the plurality of intermetallic compounds.

5. The method of claim 4 wherein dissolving the second metal layer and exposing the first metal layer further includes:
exposing the plurality of portions of the intermetallic compound and the first metal layer.

6. The method of claim 4 wherein the plurality of portions of the intermetallic compound includes a de-metallized porous layer.

7. The method of claim 3 wherein forming the molding substance on the first metal layer and within pores of the irregular surface includes:
interlocking one or more surfaces of the first metal layer and the molding substance, the molding substance filling the pores on the one or more surfaces of the first metal layer.

8. The method of claim 1 wherein the first metal layer has a first thickness and the second metal layer has a second thickness thinner than the first thickness of the first metal layer.

9. The method of claim 1 wherein the first metal layer includes copper.

10. A semiconductor structure, comprising:
a first metal structure, the first metal structure having a first surface and a second surface transverse to and extending from the first surface, the first surface having a first surface texture and the second surface having a second surface texture that is different than the first surface texture, the first surface texture having a plurality of extensions and recesses;
a first conductive layer on the second surface of the first metal structure;
a molding substance interlocking with the plurality of extensions and recesses at the first surface of the first metal structure.

11. The semiconductor structure of claim 10, further comprising a second conductive structure having a first end opposite a second end, the first end of the second conductive structure configured to electrically couple to the first conductive layer, the second end of the second conductive structure configured to electrically couple to a semiconductor substrate, the molding substance on and surrounding the first conductive layer, the second conductive structure, and the semiconductor substrate.

12. The semiconductor structure of claim 10, wherein the first metal structure including copper.

13. The semiconductor structure of claim 10, wherein the intermetallic compound having an uneven surface.

14. The semiconductor structure of claim 13, wherein the shape of the plurality of porous portions of the intermetallic compound including at least one of a sponge shape, a straw shape, a popcorn shape, or a jagged shape.

15. A semiconductor package, comprising:
a first part of a substrate having a first surface transverse to a second surface;
a second part of the substrate having a third surface transverse to a fourth surface, the fourth surface facing the second surface;
a semiconductor die on the first surface of the first part of the substrate;
a first conductive layer on the third surface of the second part of the substrate;
an intermetallic compound at the second surface of the first part of the substrate and the fourth surface of the second part of the substrate, the intermetallic compound having an irregular surface at the second surface and the fourth surface;
a second conductive structure having a first end opposite of a second end, the first end of the second conductive structure electrically coupled to the first conductive layer and the second end of the second conductive structure electrically coupled to the semiconductor die;
a molding substance interlocking with the irregular surface of the intermetallic compound at the second surface of the first part of the substrate and the fourth surface of the second part of the substrate.

16. The semiconductor package of claim 15, wherein the molding substance protruding into the irregular surface of the intermetallic compound and the molding substance surrounding the first part of the substrate, the second part of the substrate, the first conductive layer, the second conductive structure, and the semiconductor die.

17. The semiconductor package of claim 15, wherein the irregular surface of the intermetallic compound including a plurality of valleys and peaks.

18. The semiconductor package of claim 15, wherein the irregular surface of the intermetallic compound including a sponge shape, a straw shape, or a jagged shape.

19. The semiconductor package of claim 14, wherein the interlock between the molding substance and the irregular surface of the intermetallic compound including a mechanical interlock between the molding substance and the intermetallic compound.

20. The semiconductor package of claim 14, wherein the first and second part of the substrate including copper, the intermetallic compound including a compound of copper and at least one of aluminum, tin, or zinc.
